(19) United States
(12) Patent Application Publication
(10) Pub. No.: US 2013/0069728 A1
(43) Pub. Date: Mar. 21, 2013

(54) Automatic bias operational amplifying circuit and system

(71) Applicant: Fangping Fan, Chengdu (CN)

(72) Inventor: Fangping Fan, Chengdu (CN)

(73) Assignee: IPGoat Microelectronics (SiChuan) Co., Ltd.

(21) Appl. No.: 13/473,733

(22) Filed: May 17, 2012

(30) Foreign Application Priority Data
Sep. 21, 2011 (CN) 201110282052.9

(51) Int. Cl. H03F 3/04

(52) U.S. Cl. 330/296

(57) ABSTRACT

An automatic bias operational amplifying circuit, includes a control sub-circuit and an offset sub-circuit connected to the control sub-circuit. The control sub-circuit includes a first input terminal, a second input terminal, a first field-effect transistor connected to the offset sub-circuit, a second field-effect transistor connected to the first input terminal, a third field-effect transistor connected to the second input terminal, a first output terminal connected to the second field-effect transistor, a second output terminal connected to the third field-effect transistor, a first resistor connected to the first output terminal, and a second resistor connected to the second output terminal. The offset sub-circuit includes a reference voltage terminal, a comparator connected between the reference voltage terminal and the control sub-circuit, a third resistor connected between the comparator and the second output terminal, and a fourth resistor connected between the comparator and the first output terminal Its system is further provided.

### BACKGROUND OF THE PRESENT INVENTION

1. Field of Invention

The present invention relates to an operational amplifying circuit and system, and more particularly to an automatic bias operational amplifying circuit and system having an accurate output voltage swing.

2. Description of Related Arts

Refer to FIG. 1 of the drawings, which is a circuit structure of a conventional operational amplifier. If R11=R22=Rdd, it is necessary to generate an accurate current Id1=Vpp1/Rdd for getting an accurate output voltage swing Vpp1=(VOUT1+)−(VOUT1−). And in order to generate the accurate current, it generally requires to divide a reference voltage by a resistance. I.e., a current Ib1=VREF1/R33 is obtained, and then Id1=N*Ib1 is obtained by mirror, wherein N presents a mirror ratio.

A voltage VFB is forced to be equal to the reference voltage VREF1 by a comparator CMP1. Consequently, a current value I33 that flows through the resistor R33 is obtained, I33=VREF1/R33=Ib1, i.e., a current that flows through a field-effect transistor MP is Ib. If a mirror ratio of a field-effect transistor MP1 to a field-effect transistor MP2 is N, Id1=N*Ib1 is obtained. In order to ensure an accuracy of the current Ib1, an off chip resistor is usually required, which leads to a waste of large areas. Meanwhile, there is an offset of process corners between a resistor R11 and a resistor R22, which leads to an offset of the output voltage swing having a maximum value of ±20%. Certainly, the resistor R33 is capable of being matched with the resistor R11 and the resistor R22 on a layout, so as to eliminate the offset. However, accurately matching between the resistors R33 and R11, R33 and R22 increase the difficulty of a layout designing and waste areas. And meanwhile, mirror of the field-effect transistor MP1 and MP2 generates an offset as well.

Thus what can be seen from the analysis mentioned above is as follows. The structure of the conventional operational amplifier needs to generate an accurate constant-temperature offset current, so as to obtain an accurate output voltage swing and generate an accurate constant-temperature offset current. This increases the difficulty of a layout designing and wastes areas.

### SUMMARY OF THE PRESENT INVENTION

In view of the descriptions mentioned above, it is necessary to provide an automatic bias operational amplifying circuit and system having an accurate output voltage swing.

An automatic bias operational amplifying circuit, comprises a control sub-circuit and an offset sub-circuit connected to the control sub-circuit, wherein:
the control sub-circuit comprises a first input terminal, a second input terminal, a first field-effect transistor connected to the offset sub-circuit, a second field-effect transistor connected to the first input terminal, a third field-effect transistor connected to the second input terminal, a first output terminal connected to the second field-effect transistor, a second output terminal connected to the third field-effect transistor, a first resistor connected to the first output terminal, and a second resistor connected to the second output terminal; and
the offset sub-circuit comprises a reference voltage terminal, a comparator connected between the reference voltage terminal and the control sub-circuit, a third resistor connected between the comparator and the second output terminal, and a fourth resistor connected between the comparator and the first output terminal.

An automatic bias operational amplifying system, comprises a control sub-circuit and an offset sub-circuit connected to the control sub-circuit, wherein the offset sub-circuit comprises a reference voltage terminal, a comparator connected between the reference voltage terminal and the control sub-circuit, a third resistor connected between the comparator and the second output terminal, and a fourth resistor connected between the comparator and the first output terminal.

Compared with conventional arts, the automatic bias operational amplifying circuit and system of the present invention are not influenced by a process or a temperature, are capable of determining the accurate output voltage swing by regulating a reference voltage of the reference voltage terminal, without being additionally supplied with an accurate constant-temperature offset current, and greatly reduce design costs thereof.

These and other objectives, features, and advantages of the present invention will become apparent from the following detailed description, the accompanying drawings, and the appended claims.

### BRIEF DESCRIPTION OF THE DRAWINGS

FIG. 1 is a circuit diagram of a conventional operational amplifier.

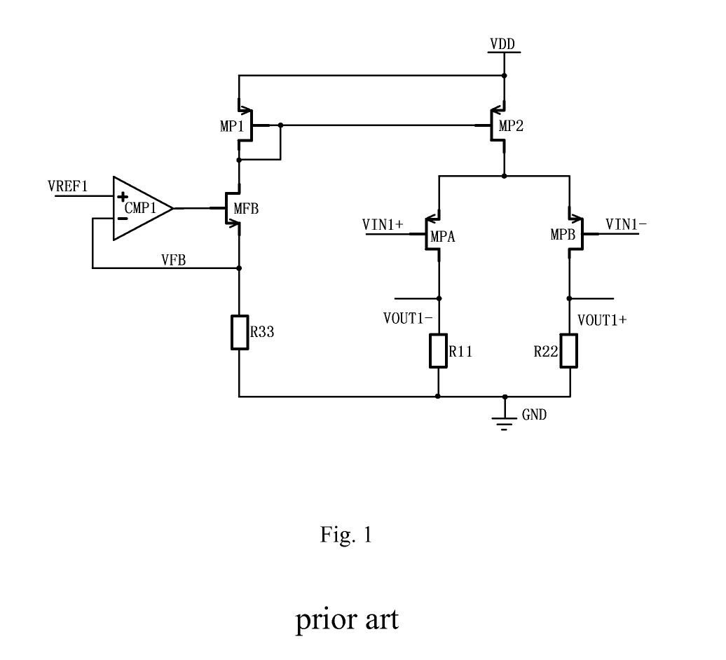

FIG. 2 is a system block diagram of an automatic bias operational amplifying system according to a preferred embodiment of the present invention.

FIG. 3 is a circuit diagram of the automatic bias operational amplifying system according to the preferred embodiment of the present invention.

### DETAILED DESCRIPTION OF THE PREFERRED EMBODIMENT

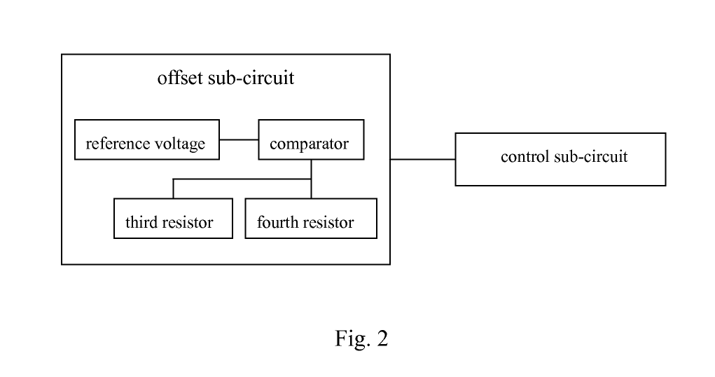

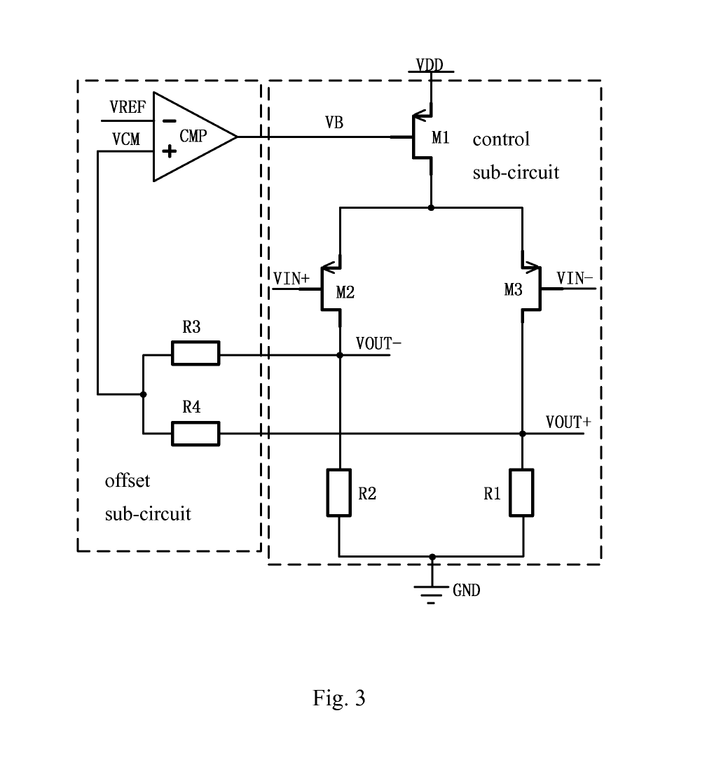

Referring to FIG. 2 of the drawings, an automatic bias operational amplifying system, according to a preferred embodiment of the present invention, comprises a control sub-circuit and an offset sub-circuit connected to the control sub-circuit. The control sub-circuit is for amplifying and then outputting an input differential signal. And the offset sub-circuit is for providing the control sub-circuit with an appropriate working current. Also referring to an automatic bias operational amplifying circuit shown in FIG. 3 of the drawing, the control sub-circuit comprises a first input terminal VIN+, a second input terminal VIN−, a first field-effect transistor M1 connected to the offset sub-circuit, a second field-effect transistor M2 connected to the first input terminal VIN+, a third field-effect transistor M3 connected to the second input terminal VIN−, a first output terminal VOUT+, a second output terminal VOUT−, a first resistor R1 connected to the first output terminal VOUT+, and a second resistor R2 connected to the second output terminal VOUT−. The offset sub-circuit comprises a reference voltage terminal VREF, a comparator CMP respectively connected to the reference voltage terminal VREF and the first field-effect transistor M1, a third resistor R3 respectively connected to the comparator CMP and the second output terminal VOUT−, and a fourth resistor R4 respectively connected to the comparator CMP and the first output terminal VOUT+. The first input terminal VIN+ and the second input terminal VIN− together receive a pair of differential signals. The first output terminal VOUT+ and the second output terminal VOUT− together output a pair of differential signals that are amplified.

According to a preferred embodiment of the present invention, specific circuit connections of the automatic bias operational amplifying circuit are as follows. A non-inverting input terminal of the comparator CMP is respectively connected to a first terminal of the third resistor R3 and a first terminal of the fourth resistor R4, an inverting input terminal of the comparator CMP is connected to the reference voltage terminal VREF; an output terminal of the comparator CMP is connected to a grid electrode of the first field-effect transistor M1 and outputs a voltage VB to a grid electrode of the first field-effect transistor M1. A source electrode of the first field-effect transistor M1 is connected to a power source terminal VDD; a drain electrode of the first field-effect transistor M1 is respectively connected to a source electrode of the second field-effect transistor M2 and a source electrode of the third field-effect transistor M3. A grid electrode of the second field-effect transistor M2 is connected to the first input terminal VIN+; a drain electrode of the second field-effect transistor M2 is respectively connected to a second terminal of the third resistor R3, a first terminal of the second resistor R2 and the second output terminal VOUT−. A grid electrode of the third field-effect transistor M3 is connected to the second input terminal VIN−; a drain electrode of the third field-effect transistor M3 is respectively connected to a second terminal of the fourth resistor R4, a first terminal of the first resistor R1 and the first output terminal VOUT+. Both a second terminal of the first resistor R1 and a second terminal of the second resistor R2 are connected to a ground terminal GND.

According to a preferred embodiment of the present invention, working principles of the automatic bias operational amplifying circuit are analyzed as follows. The first input terminal VIN+ and the second input terminal VIN− together receive a pair of differential signals. The first terminal of the third resistor R3 and the first terminal of the fourth resistor R4 detect a common-mode signal VCM of the differential signals that are received by the first input terminal VIN+ and the second input terminal VIN−, and input the common-mode signal VCM to the non-inverting input terminal of the comparator CMP. The reference voltage terminal VREF inputs a reference voltage to the inverting input terminal of the comparator CMP. The comparator CMP compares the common-mode signal VCM with the reference voltage, and regulates a tail current of the operational amplifier, i.e., a current flows through the first field-effect transistor, by regulating an output voltage VB. And an entire loop is in a stable state until the common-mode signal VCM equals to the reference voltage. Because the common-mode signal VCM equals to the reference voltage at the reference voltage terminal VREF, and the common-mode signal VCM=(½)*Vpp, wherein Vpp is an output voltage swing, the output voltage swing Vpp is regulated, and the accurate output voltage swing is obtained so long as the reference voltage at the reference voltage terminal VREF is regulated.

According to the analysis mentioned above, conclusions are obtained as follows. The automatic bias operational amplifying circuit and system of the present invention are not influenced by a process or a temperature; are capable of determining the accurate output voltage swing by regulating a reference voltage of the reference voltage terminal VREF, without being additionally supplied with an accurate constant-temperature offset current; and greatly reduce design costs thereof.

One skilled in the art will understand that the embodiment of the present invention as shown in the drawings and described above is exemplary only and not intended to be limiting.

It will thus be seen that the objects of the present invention have been fully and effectively accomplished. Its embodiments have been shown and described for the purposes of illustrating the functional and structural principles of the present invention and is subject to change without departure from such principles. Therefore, this invention includes all modifications encompassed within the spirit and scope of the following claims.

What is claimed is:

1. An automatic bias operational amplifying circuit, comprising a control sub-circuit and an offset sub-circuit connected to said control sub-circuit, wherein:
said control sub-circuit comprises a first input terminal, a second input terminal, a first field-effect transistor connected to said offset sub-circuit, a second field-effect transistor connected to said first input terminal, a third field-effect transistor connected to said second input terminal, a first output terminal connected to said second field-effect transistor, a second output terminal connected to said third field-effect transistor, a first resistor connected to said first output terminal, and a second resistor connected to said second output terminal; and
said offset sub-circuit comprises a reference voltage terminal, a comparator connected between said reference voltage terminal and said control sub-circuit, a third resistor connected between said comparator and said second output terminal, and a fourth resistor connected between said comparator and said first output terminal

2. The automatic bias operational amplifying circuit, as recited in claim 1, wherein a non-inverting input terminal of said comparator is respectively connected to a first terminal of said third resistor and a first terminal of said fourth resistor, an inverting input terminal of said comparator is connected to said reference voltage terminal, and an output terminal of said comparator is connected to a grid electrode of said first field-effect transistor.

3. The automatic bias operational amplifying circuit, as recited in claim 2, wherein a source electrode of said first field-effect transistor is connected to a power source terminal, and a drain electrode of said first field-effect transistor is respectively connected to a source electrode of said second field-effect transistor and a source electrode of said third field-effect transistor.

4. The automatic bias operational amplifying circuit, as recited in claim 3, wherein a grid electrode of said second field-effect transistor is connected to said first input terminal, and a drain electrode of said second field-effect transistor is respectively connected to a second terminal of said third resistor, a first terminal of said second resistor and said second output terminal.

5. The automatic bias operational amplifying circuit, as recited in claim 4, wherein a grid electrode of said third field-effect transistor is connected to said second input terminal, and a drain electrode of said third field-effect transistor is respectively connected to a second terminal of said fourth resistor, a first terminal of said first resistor and said first output terminal.

6. The automatic bias operational amplifying circuit, as recited in claim 5, wherein both a second terminal of said first resistor and a second terminal of said second resistor are connected to a ground terminal

7. An automatic bias operational amplifying system, comprising a control sub-circuit and an offset sub-circuit connected to said control sub-circuit, wherein said offset sub-circuit comprises a reference voltage terminal, a comparator connected between said reference voltage terminal and said control sub-circuit, a third resistor connected between said comparator and said second output terminal, and a fourth resistor connected between said comparator and said first output terminal.

8. The automatic bias operational amplifying system, as recited in claim 7, wherein said control sub-circuit comprises a first input terminal, a second input terminal, a first field-effect transistor connected to said offset sub-circuit, a second field-effect transistor connected to said first input terminal, a third field-effect transistor connected to said second input terminal, a first output terminal connected to said second field-effect transistor, a second output terminal connected to said third field-effect transistor, a first resistor connected to said first output terminal, and a second resistor connected to said second output terminal.

9. The automatic bias operational amplifying system, as recited in claim 8, wherein a non-inverting input terminal of said comparator is respectively connected to a first terminal of said third resistor and a first terminal of said fourth resistor, an inverting input terminal of said comparator is connected to said reference voltage terminal, an output terminal of said comparator is connected to a grid electrode of said first field-effect transistor, a source electrode of said first field-effect transistor is connected to a power source terminal, and a drain electrode of said first field-effect transistor is respectively connected to a source electrode of said second field-effect transistor and a source electrode of said third field-effect transistor.

10. The automatic bias operational amplifying system, as recited in claim 9, wherein a grid electrode of said second field-effect transistor is connected to said first input terminal, a drain electrode of said second field-effect transistor is respectively connected to a second terminal of said third resistor, a first terminal of said second resistor and said second output terminal, a grid electrode of said third field-effect transistor is connected to said second input terminal, a drain electrode of said third field-effect transistor is respectively connected to a second terminal of said fourth resistor, a terminal of said first resistor and said first output terminal, both a second terminal of said first resistor and a second terminal of said second resistor are connected to a ground terminal.
